(19) United States
(12) Patent Application Publication
(10) Pub. No.: US 2026/0063743 A1
(43) Pub. Date: Mar. 5, 2026

(54) SYSTEM AND METHOD FOR RECONSTRUCTION OF IMAGES FROM ULTRA-SPARSE ACQUISITIONS

(71) Applicant: The Governing Council of the University of Toronto, Toronto (CA)

(72) Inventors: Alexander James MERTENS, Toronto (CA); Hai-Ling Margaret CHENG, Etobicoke (CA)

(73) Assignee: The Governing Council of the University of Toronto, Toronto, ON (CA)

(21) Appl. No.: 19/113,484

(22) PCT Filed: Sep. 22, 2023
(86) PCT No.: PCT/CA2023/051252

§ 371 Date: Mar. 20, 2025

Related U.S. Application Data
(60) Provisional application No. 63/409,333, filed on Sep. 23, 2022.

(51) Int. Cl. G01R 33/56; G01R 33/48

(52) U.S. Cl. CPC G01R 33/5608; G01R 33/4824; G01R 33/5601

(57) ABSTRACT

Methods and systems for reconstructing MRI images from a time-series of undersampled MRI scan images. The under-sampled scan images are partitioned into subsets and combined to obtain low-temporal-resolution k-space images that are used to find an estimated spatial domain image for each subset that collectively are used to determined an estimated spatial domain subspace. For each undersampled scan image, a spatial domain reconstruction is found as a function of the estimated spatial domain subspace.

### FIELD

The present application relates to the reconstruction of images and, in particular, to reconstruction of a time-series of images from ultra-sparse magnetic resonance imaging data acquisition.

### BACKGROUND

Dynamic imaging refers to rapid imaging acquisition to capture biological events that change with time. One can readily appreciate that imaging must necessarily be rapid to ensure such dynamic phenomenon is captured accurately. In magnetic resonance imaging (MRI), this type of dynamic imaging may be paired with administering a tracer, or contrast agent, and is known as dynamic contrast-enhanced MRI, or DCE-MRI. Through measuring and analyzing the pharmacokinetics of contrast agent uptake and distribution in tissue, one can extract pharmacokinetic (PK) parameters related to tissue perfusion, microvascular volume, vessel wall leakiness, and other functional parameters critical to understanding tissue health, diagnosing disease and injury, and monitoring treatment.

Accurate DCE-MRI estimation of perfusion or other microvascular parameters requires a high temporal resolution for modeling pharmacokinetics and a high spatial resolution to identify the smallest structures. Due to hardware limitations with MRI scanning, it is impossible to satisfy both requirements, and one is traded off for the other. In most DCE-MRI applications, one normally retains high spatial resolution to permit identification of fine anatomy and sacrifices temporal resolution, a trade-off that inevitably reduces the accuracy of the reconstructed contrast-time curves. This compromise is undesirable, and efforts over the decades have attempted to accelerate acquisitions by undersampling, or by acquiring less than the full dataset, while at the same time reconstructing images at their full spatial resolution.

### BRIEF DESCRIPTION OF THE DRAWINGS

Reference will now be made, by way of example, to the accompanying drawings in which:

FIG. 1 shows, in block diagram form, an example system in accordance with the present application;

FIG. 2 is a high-level schematic diagram of an example computing device;

FIG. 3 shows a simplified organization of software components stored in a memory of the example computing device of FIG. 2;

FIG. 4 shows, in flowchart form, one example method of reconstructing MRI images;

FIGS. 5A-5D diagrammatically illustrate example radially-sampled scan images and the progression to reconstruction; and

FIG. 6 shows, in flowchart form, another example method of reconstructing MRI images.

Like reference numerals are used in the drawings to denote like elements and features.

### DETAILED DESCRIPTION

Embodiments described herein may include a system and method to reconstruct MRI images from a time series of undersampled scan images through generating an estimated low-temporal-resolution spatial domain subspace from the undersampled scan images and then using the spatial domain subspace as the basis for generating estimated reconstructions for each of the undersampled scan images.

In one aspect, the present application describes a method that may include receiving a time-series of undersampled scan images obtained using magnetic resonance imaging (MRI); segmenting the time-series into a plurality of subsets of undersampled scan images and, for each subset, combining the undersampled scan images in the subset to obtain a low-temporal-resolution k-space image for that subset; generating an estimated spatial domain image for each low-temporal-resolution k-space image to obtain a set of low-temporal-resolution estimated spatial domain images; generating a subset of representative images based on the set of low-temporal-resolution estimated spatial domain images to form an estimated spatial domain subspace; for each undersampled scan image in the time-series of undersampled scan images, determining a spatial domain reconstruction as a function of the representative images in the estimated spatial domain subspace; and outputting, as a sequence of images for video display, the spatial domain reconstructions.

In some implementations, generating the estimated spatial domain image includes using compressed sensing to generate the estimated spatial domain image.

In some implementations, generating the estimated spatial domain image includes, for each low-temporal-resolution k-space image, finding a respective estimated spatial domain image that, when transformed to k-space, best matches that low-temporal-resolution k-space image. Finding the respective estimated spatial domain image may include selecting a candidate image using a minimization expression that includes a distance measure in k-space. The minimization expression may further include a temporal total variation term and a nuclear norm.

In some implementations, generating the subset includes performing singular value decomposition to determine a singular value for each representative image, and selecting, as the subset, b of the representative images having the highest associated singular values, wherein b is a present number of basis images.

In some implementations, determining the spatial domain reconstruction includes determining a set of coefficients that, when applied to the representative images in the subset result in the spatial domain reconstruction. For each undersampled scan image, determining the set of coefficients may include finding a best match in k-space between the undersampled scan image and an undersampled transformed product of the set of coefficients and the estimated spatial domain subspace.

In some implementations, the method may further include re-performing compressed sensing using the spatial domain reconstruction as a candidate image to generate a final spatial domain reconstruction constrained to be close to the spatial domain subspace.

In some implementations, the time-series of undersampled scan images may be a time-series of radially sampled k-space scan images, a time-series of Cartesian sampled k-space scan images, or a time-series of spiral sampled k-space scan images, as examples.

In a further aspect, the present application describes a computing device that includes a processor and memory storing processor-executable instructions that, when executed by the processor, are to cause the processor to carry out one or more of the methods described herein.

According to another aspect, the present application discloses a non-transitory computer readable storage medium containing computer-executable instructions which, when executed, configure a processor to carry one or more of the methods described herein.

Other aspects and features of the present application will be understood by those of ordinary skill in the art from a review of the following description of examples in conjunction with the accompanying figures.

In the present application, the phrase “at least one of . . . or . . . ” is intended to cover any one or more of the listed elements, including any one of the listed elements alone, any sub-combination, or all of the elements, without necessarily excluding any additional elements, and without necessarily requiring all of the elements.

In some of the examples below, image data may be described as being vectorized, meaning the image data is in vector form rather than matrix form. Different implementations may use different data structures without altering the principal of the methods or functions described. A reference to a “basis vector” may be considered equivalent to a “basis image” and vice versa.

In some of the examples below, the terms “time series” are used in describing a set of images taken over a period of time. In some cases, like DCE-MRI, the changes in signal intensity observed over the course of the series of obtained images are based on injection of a contrast agent. In some cases, like MR relaxometry, the change over the series of images is based on changing imaging parameters values for the different images in the series. In some case, like dynamic imaging, at least some of the changes may be based on change in anatomy of interest over the time series. It will be appreciated that “time series” refers to a series of images taken over a time period and that the changes in image data over the imaging period in the anatomy of interest may be based on any of these causes or other causes.

In some of the examples below, radial sampling is described as the mechanism for obtaining a time-series of k-space scan images using MRI. Radial sampling is one example of undersampled scanning in MRI. Other undersampled scanning may include Cartesian (e.g. horizontal line) sampling. Yet another example of undersampled scanning is spiral sampling. Other patterns of k-space sampling may also be used to obtain a time-series of undersampled k-space scan images.

As noted above, it is difficult to achieve both high spatial resolution so as to accurately locate and identify small structures, and high temporal resolution in order to accurately identify pharmacokinetics or dynamic anatomy, such as heart function. The state of the art in MRI reconstruction comes from the work of Feng et al. as described in L. Feng et al., “Golden-angle radial sparse parallel MRI: Combination of compressed sensing, parallel imaging, and golden-angle radial sampling for fast and flexible dynamic volumetric MRI,” Magnetic Resonance in Medicine, vol. 72, no. 3, 2014, doi: 10.1002/mrm.24980; L. Feng, L. Axel, H. Chandarana, K. T. Block, D. K. Sodickson, and R. Otazo, “XD-GRASP: Golden-angle radial MRI with reconstruction of extra motion-state dimensions using compressed sensing,” Magnetic Resonance in Medicine, vol. 75, no. 2, 2016, doi: 10.1002/mrm.25665; and L. Feng, Q. Wen, C. Huang, A. Tong, F. Liu, and H. Chandarana, “GRASP-Pro: imProving GRASP DCE-MRI through self-calibrating subspace-modeling and contrast phase automation,” Magnetic Resonance in Medicine, 2020, doi: 10.1002/mrm.27903.

Feng et al. developed golden angle radial sparse parallel (GRASP) and improved GRASP (GRASP-Pro). GRASP used radial sampling and compressed sensing with a temporal total variation (TV) constraint to reconstruct under-sampled DCE-MRI data. With this as a foundation, GRASP-Pro supposes that the true DCE-MRI data lies in a low dimensional temporal subspace and enforces this in the reconstruction. First, a low spatial resolution GRASP reconstruction is performed that excludes high frequency regions of k-space. From this reconstruction, a temporal subspace is learned through singular value decomposition. Then, a high spatial resolution compressed sensing reconstruction is performed using all acquired k-space, with the reconstruction restricted to fall within the learned temporal subspace. With this method, as few as 13 radial spokes can be used to reconstruct 256×256 images.

However, restricting a reconstruction to fall within a temporal subspace is likely to lead to an underdetermined reconstruction problem, even when a perfect temporal subspace is known. The exclusion of high frequency regions of k-space in the course of determining the temporal subspace results in a loss of resolution in spatial data. This manifests as a blurriness of the reconstructed image even in the case of a perfect temporal subspace.

The present application describes a system and method of image reconstruction that includes estimating a spatial domain subspace instead of a temporal subspace. The use of a temporal subspace estimate can result in an underdetermined reconstruction problem, which may produce image anomalies and distortion in the resultant reconstruction. By using the described method of determining an estimated spatial domain subspace as the basis for reconstruction, the reconstruction problem becomes overdetermined and the quality of the reconstruction is improved.

When attempting to reconstruct undersampled k-space data from a temporal subspace, assuming radial undersampling is used for example, points in k-space over time that are closer to DC will have more datapoints for reconstruction than those further away from the DC point. In other words, the DC point in k-space over time will be fully sampled and therefore result in an overdetermined reconstruction problem, whereas points further away from the center of k-space will have fewer datapoints for reconstruction and eventually result in an underdetermined reconstruction problem. This is due to the property of radial sampling to sample more densely towards the center of k-space. Therefore, reconstruction with a temporal subspace is likely to be underdetermined in much of k-space over time, hence the need for a compressed sensing reconstruction with the temporal subspace.

In the case of reconstruction with a spatial subspace, each point in time can be considered independently, and the conditions for an overdetermined reconstruction problem change. This means that when using a spatial subspace, the theoretically achievable undersampling rates are higher than reconstruction with a temporal subspace when the same number of basis vectors are used.

In one aspect, the present application describes methods and systems for image reconstruction from undersampled MRI scans. The MRI scans are a time-series of k-space scan images obtained using an undersampling technique, such as radial sampling, Cartesian sampling, spiral sampling, or other such techniques. In particular, the methods and systems may include forming low-temporal-resolution high-spatial-resolution k-space images by segmenting the series of scan images into subsets and combining the k-space images of a subset. An estimated spatial domain image is then found for each of the low-temporal-resolution high-spatial-resolution k-space images. A representative set of images may be determined based on the full set of estimated spatial domain images. In some cases, a subset of the representative set may be selected, for example using singular value decomposition, to form an estimated spatial domain subspace.

The estimated spatial domain subspace serves as the basis vectors for building reconstructions. That is, for each undersampled scan image, a combination of the estimated images in the estimated spatial domain subspace is found that best matches the undersampled scan image in k-space. That combination, in the spatial domain, is the reconstruction of that scan image. The reconstruction is, thus, found from within the estimated spatial domain subspace.

In some cases, reconstruction may be further refined through compressed sensing so as to allow it to vary somewhat from the estimated spatial domain subspace.

It will be appreciated that in some of the illustrative examples below radial sampling is used as the technique for obtaining undersampled scan images; however, the present application may be implemented using other undersampling techniques, including Cartesian sampling, spiral sampling, and others, provided the resultant time-series may be retrospectively grouped to a desired temporal resolution through segmentation of the time-series into subsets of scan image and the combination of those scan images into respective low-temporal-resolution k-space images. One example of Cartesian sampling is a variable density Cartesian sampling method that enables preferential sampling of certain portions of k-space, as described in Rich, et al., “Cartesian sampling with Variable density and Adjustable temporal resolution (CAVA)”, Magnetic Resonance in Medicine, June 2020, vol. 84, Issue 6, pp. 2015-2025.

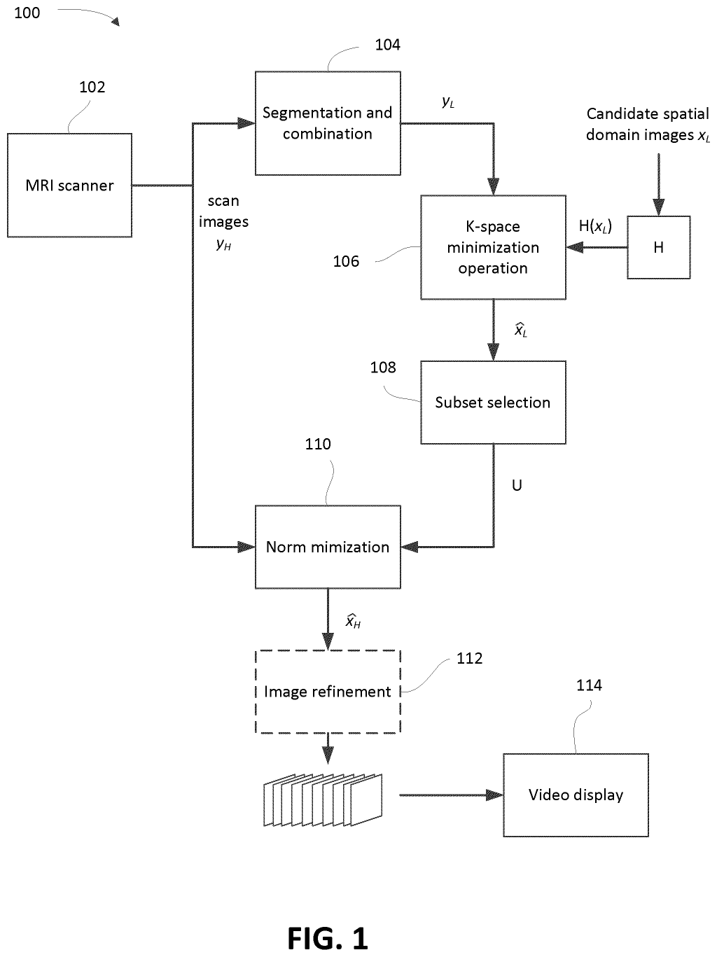

Reference will first be made to FIG. 1 which diagrammatically illustrates an example MRI image reconstruction system 100. The system 100 may be implemented using one more computing devices, which each may include one or more processors, memory, communications subsystems, and user interfaces. The memory may store processor-executable instructions that, when executed, cause the one or more processors to carry out operations in accordance with the instructions. The processor-executable instructions may be grouped into functions, modules, classes, routines, or applications dependent upon the programming language and paradigm of a particular implementation.

The system 100 may include an MRI scanner 102 that produces a time-series of scan images, y_{H}. The scan images are ultra-sparse acquisitions, acquired through radial sampling in these examples. That is, each scan image contains one or more “spokes” in k-space, where the DC point is in the centre of the 2D scan image and points further from the center correspond to higher frequencies in k-space. The scan image in general includes H spokes. In many illustrative embodiments described herein, H=1, meaning each scan image contains a single radial spoke. In some cases, the radial sampling is conducted in accordance with “golden angle” principles, meaning sequentially obtained spokes are at a particular angle relative to each other.

The time-series of scan images are input to a segmentation and combination module 104 that groups adjacent scan images into non-overlapping subsets. In other words, it partitions the full series of images into non-overlapping subsets. In one example, the time-series may contain 1000 scan images, and the segmentation and combination module 104 may segment the time-series into 50 subsets, each containing 20 scan images.

The segmentation and combination module 104 combines the scan images of each subset to produce a respective low-temporal-resolution k-space image. The combination may include adding the images of the subset to find the low-temporal-resolution k-space image. In some cases, to the extent that the spokes of the images overlap in two or more images, overlapping pixels may be averaged to find the corresponding pixel of the low-temporal-resolution k-space image. For example, the DC point at the center of the image may have a pixel value in every scan image and the resultant DC point in the low-temporal-resolution k-space image may be an average of all the DC points in the subset of scan images. The resultant low-temporal-resolution k-space image may be a multi-spoked k-space image. If there are L scan images in each subset, then the resulting low-temporal-resolution k-space image, y_{L}, has L spokes. In the example in which there are 20 scan images per subset and one radial spoke per scan image, the low-temporal-resolution k-space image features 20 spokes in k-space. Another option is to store each spoke individually for the low temporal resolution dataset, and use the non-uniform fast Fourier transform (NUFFT) on each L-spoke frame to generate the image-domain image for each low-temporal resolution image.

The low-temporal-resolution k-space images y_{L} are then used to find an estimated low-temporal-resolution spatial domain image \hat{x}_{L}, where the caret indicates it is an estimate. The generation of the estimated low-temporal-resolution spatial domain image may employ compressed sensing. In some implementations, candidate spatial domain images x_{L} are transformed into k-space and a k-space minimization operation 106 is employed to find the candidate spatial domain image that best matches the low-temporal-resolution k-space image y_{L} in k-space. For each low-temporal-resolution k-space image y_{L}, the minimization operation 106 outputs a respective estimated low-temporal-resolution spatial domain image \hat{x}_{L}. The set of these estimates defines the full range of an expected spatial subspace in which the reconstructions may be expected to fit.

Depending on the partitioning, this process may result in an excessive number of estimated images to work with. It has been found that high quality reconstruction can be achieved with relatively few basis images (e.g. basis vectors). Accordingly, in this example, the full set is reduced through subset selection 108. The subset selection 108 identifies an estimated spatial domain subspace formed from a representative set of images. The representative set of images may be a subset of the estimated low-temporal-resolution spatial domain images in one example. In another example, the estimated low-temporal-resolution spatial domain images may be used as the basis for determining a representative set of images. The determination of the representative set may employ singular value decomposition in some implementations to identify the images making the most significant potential contribution to the reconstruction. Other mechanisms or criteria may be used to select a subset in other implementations. The number b of selected images may be configurable in some cases. An administrator of the system 100 may set the value of b through a user interface. A higher number b of selected images (i.e. basis images or basis vectors) may result in additional computational complexity, but with diminishing returns on improved distortion minimization. In experimental work, it has been found that as few as 10 basis vectors can produce a near perfect reconstruction.

The resulting subset of selected estimated low-temporal-resolution spatial domain images or of representative images forms the estimated spatial domain subspace. The image data may be vectorized in some implementations, and the images may be referred to as basis image or basis vectors.

Having determined the estimated spatial domain subspace, the system 100 may then reconstruct a time-series of anatomical images from the time-series of scan images y_{H}. In particular, for each scan image a norm minimization operation 110 may be performed in k-space to find the weighted combination of basis images or basis vectors from the estimated spatial domain subspace that best matches the scan image. Using that weighted combination, in the spatial domain an estimated high-temporal-resolution spatial domain image \hat{x}_{H} is produced. The estimated high-temporal-resolution spatial domain images form the time-series of reconstructions.

In some implementations, a further refinement of the reconstructions may be carried out that allows for some variation of the reconstruction beyond the constraints of the estimated spatial domain subspace, as indicated by an optional refinement operation 112.

The time-series of reconstructed images may be output for rendering and playback as a video stream on a video display 114. The output time-series of images may be stored in memory in raw format in some implementations. In some cases, the time-series of reconstructed images may be further encoded and stored in a particular video format in memory or transmitted over a network connection to a remote computing device for display and viewing by clinicians or others.

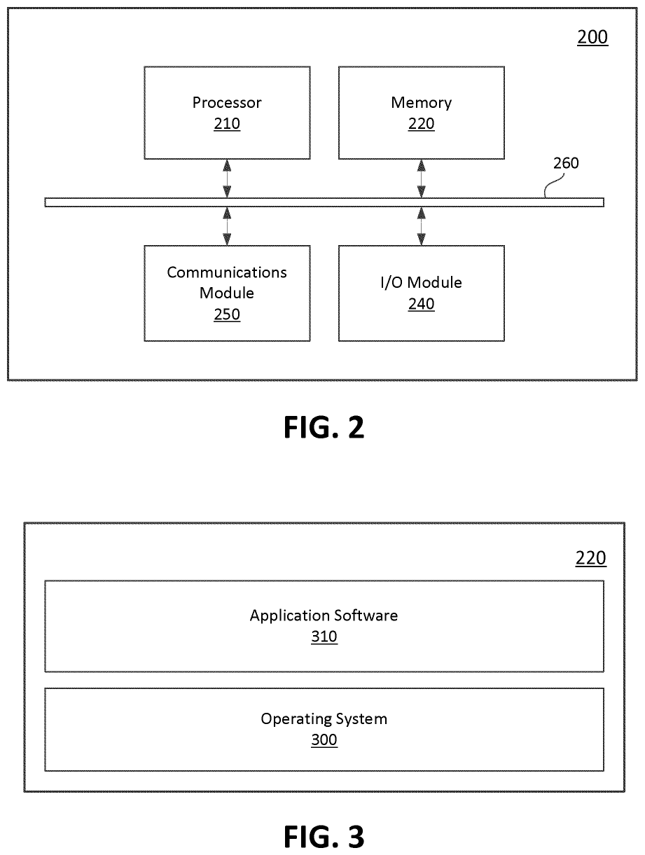

FIG. 2 is a high-level diagram of an example computing device 200. The example computing device 200 includes a variety of modules. For example, the example computing device 200 may include a processor 210, a memory 220, an I/O module 240, and a communications module 250. As illustrated, the foregoing example modules of the example computing device 200 are in communication over a bus 260.

The processor 210 is a hardware processor. The processor 210 may, for example, be one or more ARM, Intel x86, PowerPC processors, or the like.

The memory 220 allows data to be stored and retrieved. The memory 220 may include, for example, random access memory, read-only memory, and persistent storage. Persistent storage may be, for example, flash memory, a solid-state drive or the like. Read-only memory and persistent storage are a computer-readable medium. A computer-readable medium may be organized using a file system such as may be administered by an operating system governing overall operation of the example computing device 200.

The I/O module 240 allows the example computing device 200 to receive input signals and to transmit output signal. Input signals may, for example, correspond to input received from a user. Some output signals may, for example, allow provision of output to a user. The I/O module 240 may serve to interconnect the example computing device 200 with one or more input devices. Input devices may, for example, include one or more of a touchscreen input, keyboard, trackball or the like. The I/O module 240 may serve to interconnect the example computing device 200 with one or more output devices. Output devices may include, for example, a display screen such as, for example, a liquid crystal display (LCD), a touchscreen display. Additionally, or alternatively, output devices may include devices other than screens such as, for example, a speaker, indicator lamps (such as, for example, light-emitting diodes (LEDs)), and printers.

The communications module 250 allows the example computing device 200 to communicate with other electronic devices and/or various communications networks. For example, the communications module 250 may allow the example computing device 200 to send or receive communications signals. As an example, the communication module 250 may include a network connection, data port, or the like, for receiving scan images from an MRI scanner. Communications signals may be sent or received according to one or more protocols or according to one or more standards. For example, the communications module 250 may allow the example computing device 200 to communicate via a cellular data network, such as for example, according to one or more standards such as, for example, Global System for Mobile Communications (GSM), Code Division Multiple Access (CDMA), Evolution Data Optimized (EVDO), Long-term Evolution (LTE) or the like. Additionally, or alternatively, the communications module 250 may allow the example computing device 200 to communicate using near-field communication (NFC), via Wi-Fi™, via the Ethernet family of network protocols, using Bluetooth™ or via some combination of one or more networks or protocols. In some embodiments, all or a portion of the communications module 250 may be integrated into a component of the example computing device 200. In some examples, the communications module may be integrated into a communications chipset.

Software instructions are executed by the processor 210 from a computer-readable medium. For example, software may be loaded into random-access memory from persistent storage within memory 220. Additionally, or alternatively, instructions may be executed by the processor 210 directly from read-only memory of the memory 220.

FIG. 3 depicts a simplified organization of software components stored in memory 220 of the example computing device 200. As illustrated, these software components include, at least, application software 310 and an operating system 300.

The application software 310 adapts the example computing device 200, in combination with the operating system 300, to operate as a device performing a particular function. While a single application software 310 is illustrated in FIG. 3, in operation, the memory 220 may include more than one application software and different application software may perform different operations.

The operating system 300 is software. The operating system 300 allows the application software 310 to access the processor 210, the memory 220, the I/O module 240, and the communications module 250. The operating system 300 may, for example, be iOS™, Android™, Linux™, Microsoft Windows™, or the like.

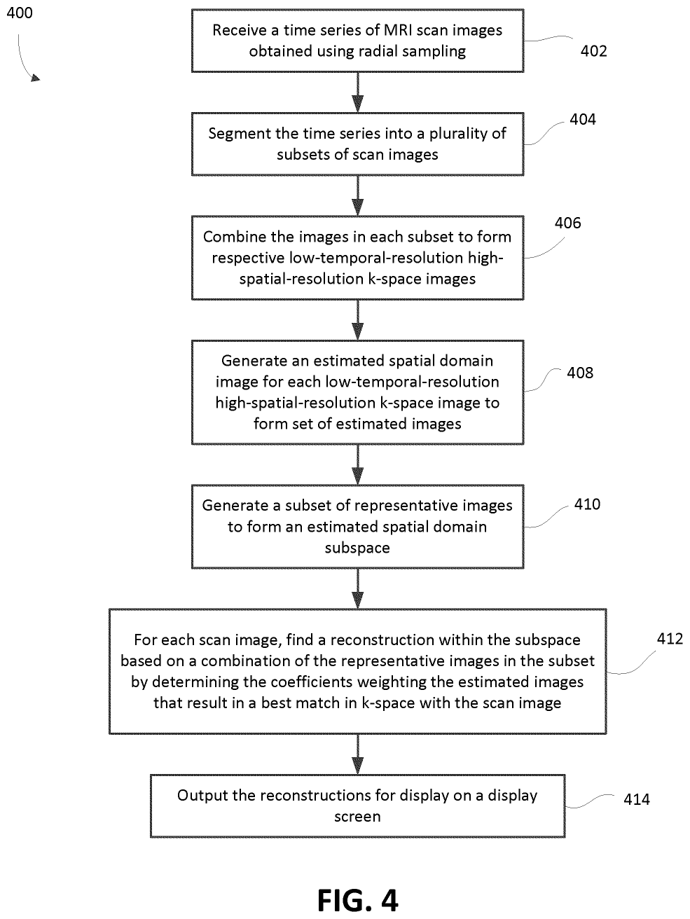

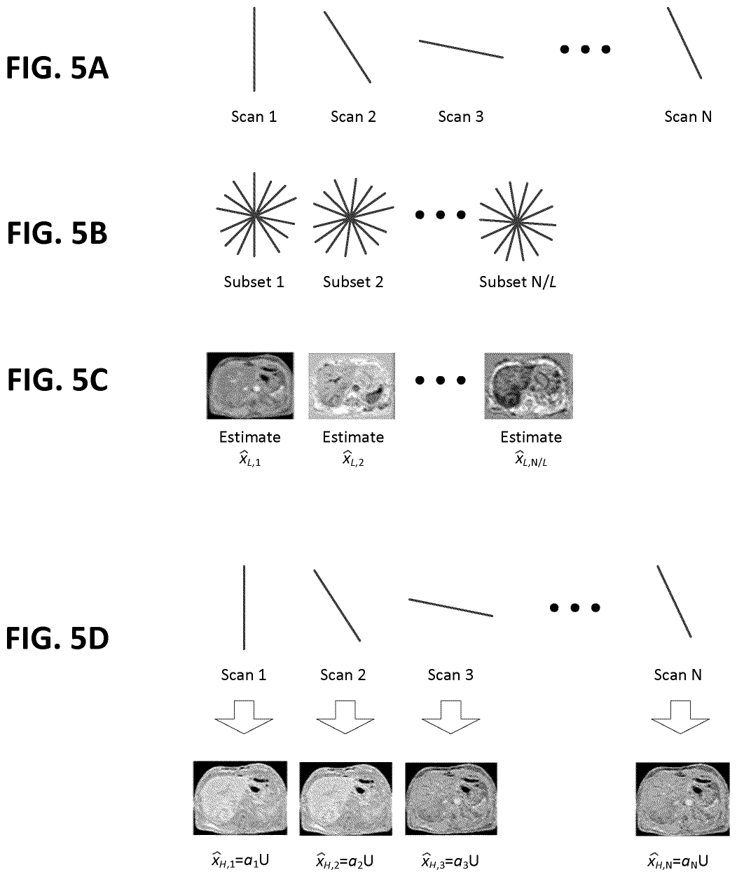

Reference will now be made to FIG. 4, which shows, in flowchart form, one example method 400 of reconstructing a time-series of images from MRI scan images. The method 400 may be implemented using one or more computing devices and processor-executable instructions stored in memory. In some cases, the computing device may be integrated within an MRI machine. In some cases, the computing device may be external to and separate from the MRI machine. The MRI machine may be configured to obtain a time series of radially-sampled scan images of a subject. FIG. 4 will be described below in conjunction with FIGS. 5A-5D.

In operation 402, the computing device receives a time series of MRI scan images obtained using radial sampling. Each image may include H radial spokes. In some implementations, H=1. FIG. 5A shows an example illustration of N scan images with a single radial spoke per image.

The computing device then segments the time series of MRI scan images into non-overlapping subsets of sequential scan images in operation 404. The plurality of subsets each contain L MRI scan images with H spokes in each image. In operation, 406, the computing device combines the L images in each subset to form a respective low-temporal-resolution high-spatial-resolution k-space image. The combination may, in some cases, include adding the images together. To the extent that the scan image contain pixel values at overlapping points, those values may be averaged or otherwise combined to find the value at the corresponding pixel location of the low-temporal-resolution high-spatial-resolution k-space image, y_{L}. FIG. 5B diagrammatically illustrates the example low-temporal-resolution high-spatial-resolution k-space images for the N/L subsets.

By creating the low-temporal-resolution high-spatial-resolution k-space image, y_{L}, the computing device has created a k-space image assembled from radially-sampled k-space images taken over a short time period, thereby resulting in low temporal resolution, but potentially high spatial resolution due to the inclusion of a number of radial samples. Using these k-space images (one per subset of scan images), the computing device may then, for each k-space image, estimate the spatial-domain image that would produce the k-space image. As indicated by operation 408, the computing device may generate an estimated spatial domain image, \hat{x}_{L}, for each low-temporal-resolution high-spatial-resolution k-space image, y_{L}. In some implementations, the computing device may employ compressed sensing in generating the estimated spatial domain images. The result is a set of estimated spatial domain images that is a low-temporal-resolution spatial domain estimate of the fully sampled dataset. The purpose of this estimate is not to accurately capture the temporal dynamics of the contrast-time curves, but to provide enough information to estimate a spatial subspace in which a higher temporal resolution would lie. FIG. 5C illustrates the estimated low-temporal-resolution spatial domain images corresponding to the N/L subsets.

In some implementations, the computing device may determine a subset of the set of estimated spatial domain images in operation 410. In some examples, the determination of the subset may include selecting the subset from the set of estimated spatial domain images. In some cases, the subset may be selected by determining a set of representative images based on the set of estimated spatial domain images. The subset may be selected based on a measure of significance or importance of the estimated spatial domain images in the set so as to reduce the number of basis images to a more manageable subset. In some cases, all images of the set are used as basis images. In some cases, the number of images in the set may be excessively large and a smaller subset may be formed to make subsequent operations more computationally practical. The number, b, of estimated spatial domain images in the subset may be configurable and may be set by policy or by an administrator. In some cases, it has been found that about 10, or even as few as 6, basis images may be sufficient to provide a near-perfect reconstruction using the present method. The resulting subset defines the estimated spatial domain subspace. This subspace is defined by the estimated spatial domain images, which may be vectorized and form a matrix U in some implementations.

Having determined the estimated spatial domain subspace, U, the computing device then generates, for each MRI scan image in the time series of scan images, an estimated spatial domain reconstruction image \hat{x}_{H} in operation 412. The estimate may be generated through finding a combination of the basis images in the estimated spatial domain subspace U that, in k-space, most closely matches the original scan image y_{H}. The combination of basis images may include a weighting of the basis images, i.e. through finding coefficients that weight the contribution of each basis image that results in a best match with the original scan image. The evaluation may be carried out in k-space. The weighted combination of basis images is spectrally transformed into k-space and undersampled to result in a radial spoke that corresponds to the radial spoke of the original scan image, and the coefficients are adjusted to find the weighted combination that results in the best match in k-space. This operation may be referred to as an L2 norm minimization constrained by the learned estimated spatial domain subspace U. FIG. 5D illustrates the high-temporal-resolution, high-spatial-resolution, estimated spatial domain reconstruction images corresponding to the original scan images.

The series of high-temporal-resolution, high-spatial-resolution, estimated spatial domain reconstruction images \hat{x}_{H} may then be output for display as a time-series of images, e.g. as a video, in operation 414. The output may include saving the images to memory, encoding the images using a video encoder and saving the resultant compressed encoded video file, and/or displaying the images on a display screen.

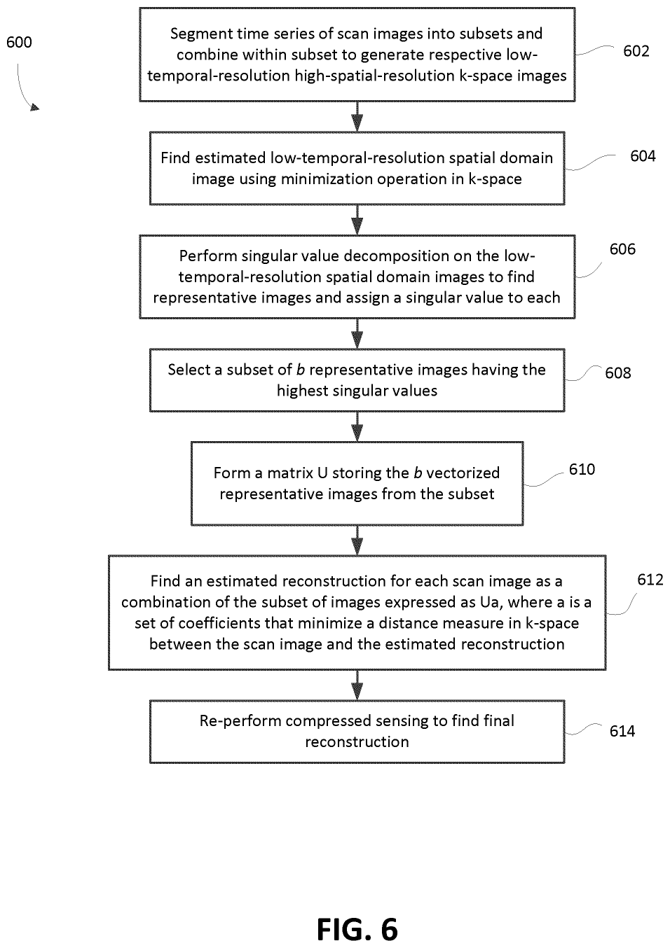

Reference will now be made to FIG. 6, which shows, in flowchart form, another example method 600 for generating spatial domain reconstruction images from a time series of MRI scan images. The method 600 may be implemented using one or more computing devices and processor-executable instructions stored in memory. In some cases, the computing device may be integrated within an MRI machine. In some cases, the computing device may be external to and separate from the MRI machine. The MRI machine may be configured to obtain a time series of radially-sampled scan images of a subject.

In operation 602, the computing device segments or partitions the time series of MRI scan images into non-overlapping subsets of scan images and combines the scan images within each subset to produce a set of respective low-temporal-resolution high-spatial-resolution k-space images y_{L}. As noted above, combining the scan images may include adding them on a pixel-by-pixel basis, while averaging the value of any pixels that have values in more than one of the scan images. The scan images are in k-space, meaning the combined image is also in k-space. If the NUFFT is used, the combination of spokes and transformation from k-space into the image domain can happen at once.

In operation 604, the computing device then finds, for each combined k-space image y_{L}, an estimated low-temporal-resolution spatial domain image \hat{x}_{L}. The finding of the estimated low-temporal-resolution spatial domain image may be based on a minimization expression that employs a distance measure in k-space. In this example, the estimate is based on an L2-norm evaluated in k-space. In one implementation, the estimate may be based on the following expression:

$${\hat{x}}_{L} = {min}_{{x}_{L}} \{ {‖ {Hx}_{L} - {y}_{L} ‖}_{2}^{2} + λ {‖ {}^{TV} ( {x}_{L} ) ‖}_{2}^{2} + γ {‖ {x}_{L} ‖}_{*} \} \qquad ( 1 )$$

In the above expression (1), y_{L} is the k-space combined image corresponding to one of the subsets of L scan images, x_{L} is a candidate spatial domain image, His an undersampling transform, e.g. a Fourier matrix or other spectral transform, that corresponds to the k-space in which y_{L} is obtained, TV performs temporal total variation which is a numerical gradient in the temporal direction, ∥⋅∥_{w} is the nuclear norm, and parameters λ and γ are balancing parameters trading off the impact of the L2 norm and the nuclear norm. The temporal total variation term measures sparsity in the temporal variation domain. The nuclear norm measures sparsity in the spatial subspace dimensionality domain. Note that in some implementations, an L1 norm may be used instead of an L2 norm.

The output of expression (1) is an estimated low-temporal-resolution spatial domain image \hat{x}_{L} for each of the N/L subsets, which collectively form an estimated subspace within which the reconstructions may be expected to lie.

In many cases, the number of subsets, and the consequent number of estimated spatial domain images defining the subspace, may be unnecessarily large. The computing device may select a subset of the estimated images to form the estimated spatial domain subspace. In some cases, the subset may be determined by finding a set of representative images based on the set of estimated spatial domain images. In particular, in operation 806, the computing device in this example may perform singular value decomposition on the set of estimated low-temporal-resolution spatial domain images in order to find the set of representative images. The singular value decomposition produces representative images and assigns a singular value to each of the representative images. In operation 808, the computing device may select b images having the highest associated singular values from the singular value decomposition operation. The selected images become the basis images (or basis vectors, if the image data is vectorized).

In operation 610, the vectorized selected images may be, in this example, stored as a matrix U. The matrix U defines the estimated subspace. With the b image vectors stored as columns in the matrix, for example. The computing device may then determine a high-temporal-resolution estimate for a scan image, y_{H}, as a function of the subspace matrix U. As indicated by operation 612, the spatial domain estimate \hat{x}_{H} is determined by finding a set of estimated coefficients, â, that, when applied to an undersampled transformed version of the matrix U in k-space result in a best fit with the original scan image y_{H}. In some examples, the computing device may be said to be solving the expression:

$${\hat{x}}_{H} = U \hat{a} \qquad ( 2 )$$

In expression (2), the coefficients are found by solving:

$$\hat{a} = {min}_{a} {‖ {U}_{kS} a - {y}_{H} ‖}_{2}^{2} \qquad ( 3 )$$

In expression (3), â is the matrix of coefficients corresponding to the optimal weights of each basis vector to construct each time point in the dataset, a is a candidate for the coefficients, and U_{kS} is the matrix U in k-space after an undersampling Fourier transform having the same undersampling pattern as the scan image y_{H}, i.e. to form H spokes in k-space.

In the case that there are more sampled points in y_{H} than basis vectors in U, then â has a closed form solution:

$${\hat{x}}_{H} = {U ( {U}_{kS}^{H} {U}_{kS} )}^{- 1} {U}_{kS}^{H} {y}_{H} \qquad ( 4 )$$

The resultant high-temporal-resolution reconstructed images, \hat{x}_{H}, lie in the learned spatial domain subspace U. The reconstructed spatial domain images may then be output and displayed on a display screen. The display may be in sequence in the form of a video. In some cases, the images stored in memory in raw form or may be compressed by a video encoder using a video coding algorithm.

While the method 600 described above results in a good quality estimate, it may be the case that the true dataset lies near the learned subspace rather than in it. Accordingly, in some implementations the method 600 may be supplemented by an optional operation 614 that re-performs compressed sensing with slightly relaxed constraints on the spatial subspace. That is, the reconstructed image may be re-estimated using the obtained \hat{x}_{H} in a minimization expression that uses temporal variation and nuclear norms to strongly bias the outcome to lie close to or within the estimated subspace. An example minimization expression is:

$${\hat{x}}_{H , final} = {min}_{{\hat{x}}_{H}} \{ {‖ H {\hat{x}}_{H} - {y}_{H} ‖}_{2}^{2} + λ {‖ {}^{TV} ( {\hat{x}}_{H} ) ‖}_{1} + γ {‖ {\hat{x}}_{H , mod} ‖}_{*} \} \qquad ( 5 )$$

In expression (5), \hat{x}_{H, final} is the output final refined reconstruction image, \hat{x}_{H} is a candidate estimate, the initialization for which is obtained in operation 610, and \hat{x}_{H, mod} is a modified candidate estimate with the basis vectors of U appended to \hat{x}_{H}. The purpose of the modified candidate estimate in the nuclear norm is to strongly suggest that the final reconstruction lie close to the estimated subspace.

An implementation in accordance with FIG. 6 was tested, using 1000 frames of 200×200 pixel images, undersampled at one spoke per frame. Furthermore, fully sampled first and last frames were prepended and appended respectively to the dataset, resulting in 1002 total time points. Since there are no temporal dynamics prior to injection of contrast agent, it is possible to fully sample the first temporal frame. Furthermore, once the contrast agent has completed its course, the images will not change in signal intensity over time, allowing the last temporal frame to be fully sampled as well. The parameters L=25, λ=0.25, and γ=0.5 were selected to generate the low temporal resolution dataset. Then, a spatial subspace was generated from this result and the initial high-resolution estimate \hat{x}_{H} was created. Then, with this as initialization, equation (5) was solved to create the final output with H=1, λ=0.25, and γ=4.5.

As a point of comparison, GRASP-Pro was also evaluated. However, rather than estimating a temporal subspace as per the first step of GRASP-Pro, ground truth temporal subspace vectors were provided to the reconstruction algorithm. The purpose of this is to compare the proposed algorithm against GRASP-Pro when GRASP-Pro has perfectly estimated a temporal subspace. Two implementations of GRASP-Pro were evaluated: one with 7 temporal basis vectors used for reconstruction, and one with 16 temporal basis vectors used for reconstruction.

The results of the reconstructions were evaluated using means-squared-error (MSE). For both abdomen and brain datasets, the presently-described method outperforms GRASP-Pro reconstruction even if the GRASP-Pro is given a perfect temporal subspace. Based on MSE comparisons, the presently-described method offers more accurate reconstructions compared to the GRASP-Pro. The improvement is seen visually in the reconstructions. At the point of highest MSE the presently-described method shows indistinguishable deviation from the ground-truth image, whereas the GRASP-Pro method produces an image of noticeably degraded quality and sharpness.

In the above-described example methods, an L2 norm was used in many expressions, however it will be appreciated that other optimizations other than L2 norm may be used in some implementations.

The above-described examples use DCE-MRI as an example context in which to perform the MRI scan image reconstruction. The use of a contrast agent typically necessitates a time series of scans that record the change over time to evaluate tracer flow velocity and tracer accumulation. The time series enables the analysis of contrast agent uptake and distribution in order to extract pharmacokinetic parameters to analyze tissue health, etc. It is presumed in many such applications that the subject anatomy is positionally static.

The examples described above include application of the method to DCE-MRI data where a contrast agent is injected and signal intensity of static anatomy changes over time. However, it may be appreciated that it does not matter what causes the change in contrast, so long as signal intensity of static anatomy changes over time. Therefore, the methods and systems can be applied to any situation in which signal intensity changes over time, whether signal inherently changes with time (as in the case of DCE-MRI) or signal changes due to time-varying image parameter settings, such as in the case of MR relaxometry.

MR relaxometry is a measurement underlying all quantitative MRI methods. In performing MR relaxometry, a series of images is acquired for different sets of imaging parameters. Once the parameter space required for accurate relaxometry measurements is spanned, a curve fitting process is applied to each pixel location to determine the quantity of interest (e.g. T1 or T2 relaxation time). Applying the presently-described methods in this context accelerates acquisitions for MR relaxometry, since a full image need not be acquired for each new parameter value.

The presently-described methods may also have application to the imaging of dynamic anatomy. A ‘state model’ may describe correlations between adjacent time points and can be used to well describe any organ that exhibits periodic motion and can provide excellent prior information for the linear reconstruction operation. A typical state model may take the form:

$$\begin{matrix}{x}_{t} = {A}_{t} {x}_{t - 1} + {b}_{t} + {μ}_{t} \\ {μ}_{t} ∼ N ( 0 , {C}_{u , t} )\end{matrix} \qquad ( 6 )$$

In expression (6), xₜ and xₜ₋₁ represent the current and previous time point in the dataset, Aₜ is a ‘state transition matrix’ that linearly links the previous and current time points, bₜ is a bias vector, and μₜ is a noise vector that accounts for any unpredictability in the transition between time points drawn from a normal distribution with a mean of 0 and a variance of Cᵤ. Typically, Aₜ, bₜ, and Cᵤ are all estimated prior to reconstruction.

Specifically, for images that exhibit motion that can be modelled, such as those of the heart, lungs, kidney, arteries, etc., these quantities can be estimated, and the state space can be used to arrive at a better subspace-constrained linear reconstruction in the case of appreciable measurement noise.

To adapt the above-described methods, we may modify expression (2) to reflect the fact that it now involves statistical quantities:

$$\begin{matrix}{\hat{x}}_{H} = U \hat{a} \\ \hat{a} = {min}_{a} E [ {‖ {U}_{kS} a - {y}_{H} ‖}_{2}^{2} ] \\ {x}_{H , t} = {A}_{t} {x}_{H , t - 1} + {b}_{t} + {μ}_{t} \\ {y}_{H , t} = {H}_{t} {x}_{H , t} + {w}_{t} \\ {μ}_{t} ∼ N ( 0 , {C}_{u , t} ) \\ {w}_{t} ∼ N ( 0 , {C}_{w , t} )\end{matrix}$$

Here, U, U_{kS}, a, and â carry the same meanings described above. U defines a matrix with vectorized subspace vectors as columns, U_{kS} is a matrix with vectorized undersampled k-space subspace vectors as columns, and a and â represent the candidate and final estimated coefficients used to build the reconstructed DCE-MRI dataset respectively. It differs in that the state model relates adjacent columns of x_{H}, a measurement model that relates the state model to the measured k-space via a linear transform Hₜ and a noise vector wₜ, and the fact the expression now minimizes the expected value of the L2 norm to find â. The goal is to find the optimal â such that \hat{x}_{H} best matches the state and measurement models.

Since it may be assumed that the ground truth data lies in the subspace spanned by the columns of U, we can make the following substitution:

$${x}_{H} = Ua$$

Applying this substitution, modified state spaces and measurement models are realized that may be expressed as:

$$\begin{matrix}{a}_{t} = {( {U}^{H} U )}^{- 1} {U}^{H} {A}_{t} {Ua}_{t - 1} + {( {U}^{H} U )}^{- 1} {U}^{H} {b}_{t} + {( {U}^{H} U )}^{- 1} {U}^{H} {μ}_{t} \\ {y}_{H , t} = {H}_{t} {Ua}_{t} + {w}_{t} \\ {μ}_{t} ∼ N ( 0 , {C}_{u} ) \\ {w}_{t} ∼ N ( 0 , {C}_{w} )\end{matrix} \qquad ( 7 )$$

In the above expression (6), aₜ is a column of â. After one more round of substitution, these equations may be expressed in a form for which solutions can readily be applied to find the optimal â:

$$\begin{matrix}{a}_{t} = {\tilde{A}}_{t} {a}_{t - 1} + {( {U}^{H} U )}^{- 1} {U}^{H} {b}_{t} + {( {U}^{H} U )}^{- 1} {U}^{H} {μ}_{t} \\ {y}_{H , t} = {U}_{kS} {a}_{t} + {w}_{t} \\ {\tilde{u}}_{t} ∼ N ( 0 , {\tilde{C}}_{u , t} ) \\ {w}_{t} ∼ N ( 0 , {C}_{w , t} ) \\ {\tilde{A}}_{t} = {( {U}^{H} U )}^{- 1} {U}^{H} {A}_{t} U \\ {\tilde{b}}_{t} = {( {U}^{H} U )}^{- 1} {U}^{H} {b}_{t} \\ {\tilde{u}}_{t} = {( {U}^{H} U )}^{- 1} {U}^{H} {u}_{t} \\ {\tilde{C}}_{u , t} = {( {U}^{H} U )}^{- 1} {U}^{H} {C}_{u , t} {U ( {U}^{H} U )}^{- 1}\end{matrix} \qquad ( 8 )$$

The above expressions (8) may be solved in a causal or non-causal manner. For a causal solution, the reconstruction of the current time point may only depend on current and past measurements. For a non-causal solution, the reconstruction of the current time point will depend on all future and past measurements. A Wiener filter solution is expressed as:

$$\hat{a} = {C}_{{ay}_{H}} {C}_{{y}_{H} {y}_{H}}^{- 1} {y}_{H} \qquad ( 9 )$$

In expression (9), C_{ay}_{_{H}} is the cross-covariance matrix that relates the vectorized measured data to the vectorized subspace vector coefficients, and C_{y}_{_{H}}_{y}_{_{H}} is a covariance matrix that relates the vectorized measured data to itself. In a dataset with N×N pixel images and T time points, this method involves inverting an N×N×T by N×N×T matrix. In many cases, this is not feasible and Kalman filter/smoother solutions may be used.

The Kalman filter is an optimal causal method of reconstruction in this case. The solution to the Kalman filter is written below given the previously mentioned state space and measurement model.

$$\begin{matrix}{\hat{a}}_{t \vert t - 1} = {\tilde{A}}_{t} {\tilde{a}}_{t - 1} \\ {M}_{t \vert t - 1} = {\tilde{A}}_{t} {M}_{t - 1 \vert t - 1} {\tilde{A}}_{t}^{H} + {\tilde{C}}_{u , t} \\ {K}_{t} = {M}_{t \vert t - 1} {{U}_{kS}^{H} ( {C}_{w , t} + {U}_{kS} {M}_{t \vert t - 1} {U}_{kS}^{H} )}^{- 1} \\ {\tilde{a}}_{t} = {\hat{a}}_{t \vert t - 1} + {K}_{t} ( {y}_{H , t} - {U}_{kS} {\hat{a}}_{t \vert t - 1} ) \\ {M}_{t \vert t} = ( I - {K}_{t} ) {U}_{kS} {M}_{t \vert t - 1}\end{matrix} \qquad ( 10 )$$

The Kalman filter can be turned into an optimal non-causal reconstruction method by running a backward pass of the filter after the initial forward pass. This is called Kalman smoothing, and it produces the same result as a Wiener filter. Here, t starts at T and decreases by 1 each step:

$$\begin{matrix}{C}_{t} = {M}_{t \vert t} {\tilde{A}}_{t + 1}^{H} {M}_{t \vert t - 1}^{- 1} \\ {\hat{a}}_{t \vert T} = {\hat{a}}_{t} + {C}_{t} ( {\hat{a}}_{t + 1 \vert T} - {\tilde{A}}_{t + 1} {\tilde{a}}_{t} ) \\ {\tilde{M}}_{t} = {M}_{t \vert t} + {C}_{t} ( {\tilde{M}}_{t + 1} - {\tilde{M}}_{t \vert t - 1} ) {C}_{t}^{- 1}\end{matrix} \qquad ( 11 )$$

The output of this algorithm is â_{T} of which â_{t|T} are columns. This output is equal to that of the previously described Wiener filter.

In some implementations, the foregoing processes may be modified to provide for spatial subspace enhancement. That is, the above-described process, or a variant of it, may be used to find an estimated spatial subspace. The estimated subspace may then be used to generate a reconstructed image. However, if the subspace is not extensive or expressive enough, then the reconstructed image will differ to some degree from the original sampled data. Using the following process, that difference or error may be used to generate an additional spatial subspace or, as will be discussed below, to enhance or refine the estimated spatial subspace.

In the following example, the images of a DCE-MRI dataset are assumed to be N×N pixels. A total of T radial lines or T Cartesian lines are acquired during sampling. In this example, it may be assumed that the sampling is Cartesian sampling rather than radial sampling.

The first step, as described above, is to segment the time series of samples into groups of L images and, for each group to find a low-temporal high-spatial-resolution reconstruction. The reconstruction may employ the following equation:

$${\hat{x}}_{L} = {min}_{{x}_{L}} {‖ {Ex}_{L} - {y}_{L} ‖}_{2}^{2} + λ {‖ TV ( {x}_{L} ) ‖}_{1} + γ {‖ {x}_{L} ‖}_{*} \qquad ( 12 )$$

In the above expression, \hat{x}_{L}∈

$${ℂ}^{{N}^{2} \times \frac{T}{L}}$$

is the estimated low temporal resolution dataset at L lines per frame and each estimated image is vectorized as a column in the matrix (a Casorati matrix), and x_{L} is a candidate estimate for \hat{x}_{L}. E=ΦFB is an encoding operator that includes three operations: Φ is k-space under-sampling, F is a non-uniform fast Fourier transform (NUFFT), and B are coil sensitivity maps. y_{L}are the vectorized and temporally sorted under-sampled measurements at L lines per frame. TV performs temporal total variation (a numerical gradient in the temporal direction), and ∥⋅∥_{*} is the nuclear norm (a sparsity constraint on the singular values of x). λ and γ are regularization parameters for the L1 temporal TV and nuclear norm, respectively. The purpose of \hat{x}_{L} is not to capture temporal dynamics accurately but, rather, to provide enough information to estimate a spatial subspace in which a higher temporal resolution dataset is hypothesized to lie.

Singular value decomposition is then performed on the low temporal-resolution output of equation (12).

$${\hat{x}}_{L} = U {A}_{L} \qquad ( 13 )$$

In the above expression, U∈

$${ℂ}^{{N}^{2} \times \frac{T}{L}}$$

is the spatial subspace and A_{L}∈

$${ℂ}^{\frac{T}{L} \times \frac{T}{L}}$$

are the coefficients to reconstruct the low temporal resolution estimate \hat{x}_{L}. The b basis vectors (i.e. spatial subspaces) with the largest singular values are retained such that U_{b}A_{Lb}≈UA_{L}, where U_{b}∈ [symbol] , and A_{Lb}∈

$${ℂ}^{b \times \frac{T}{L}} .$$

Turning back to the acquired sampled data, it is re-organized into H lines per frame, where H<L. A high-temporal reconstruction is then performed using the following equations:

$${\hat{x}}_{H} = {U}_{b} {\hat{A}}_{H} {\hat{A}}_{H} = {min}_{{A}_{H}} {‖ {EU}_{b} {A}_{H} - {y}_{H} ‖}_{2}^{2} \qquad ( 14 )$$

where \hat{x}_{H}∈

$${ℂ}^{{N}^{2} \times \frac{T}{H}}$$

is a high temporal resolution estimate of the dataset. Â_{H}∈

$${ℂ}^{b \times \frac{T}{H}}$$

is the matrix of coefficients corresponding to the optimal weights of each basis vector, and A_{H} is a candidate for Â_{H}. y_{H} are the vectorized and temporally sorted measured k-space lines at H lines per frame. If there are more sampled points per frame (typically more than 100 points) in y_{H} than basis vectors (typically 10 to 50), which is almost certainly the case, then Â_{H} has a closed form solution:

$${\hat{A}}_{H} = {( {U}_{b}^{H} {E}^{H} E {U}_{b} )}^{- 1} {U}_{b}^{H} {E}^{H} {y}_{H} \qquad ( 15 )$$

This leads to an initial high-temporal resolution estimate of the dataset constrained to lie in the estimated subspace U_{b} and is given by:

$${\hat{x}}_{H} = {{U}_{b} ( {U}_{b}^{H} {E}^{H} E {U}_{b} )}^{- 1} {U}_{b}^{H} {E}^{H} {y}_{H} \qquad ( 16 )$$

In some cases, the learned subspace, U_{b}, may not be expressive enough to produce a perfectly correct reconstruction. To correct for this, the error between the subspace representation of the measured data and the measured data itself may be determined, for example using the following expression:

$$Err = {U}_{b} {\hat{A}}_{H} - {y}_{H} \qquad ( 17 )$$

Here, Err is what the subspace is unable to represent. Ideally this contains no information; however, if the subspace is not expressive enough, there will be structural detail emerging in Err. The error images can be reconstructed by solving:

$$\hat{x} = {min}_{x} {‖ Ex - Err ‖}_{2}^{2} + λ {‖ TV ( x ) ‖}_{1} + γ {‖ x ‖}_{*} \qquad ( 18 )$$

In the above expression, \hat{x} represents the reconstructed error images, and x represents candidate reconstruction images. All other variables are as described earlier. The error images may then be used to update the subspace and make it more expressive by performing a singular value decomposition on x, similar to what is described in connection with expression (13) above. The basis vectors that correspond to large singular values may be retained and append to U_{b} to generate an enhanced estimated spatial subspace. Accordingly, the enhanced estimated spatial subspace U_{b} contains more basis vectors and is more expressive. The estimated spatial subspace U_{b} may be updated multiple times by repeating the process describe above in connection with expressions (14) through (18), decreasing the value of H each time.

The various embodiments presented above are merely examples and are in no way meant to limit the scope of this application. Variations of the innovations described herein will be apparent to persons of ordinary skill in the art, such variations being within the intended scope of the present application. In particular, features from one or more of the above-described example embodiments may be selected to create alternative example embodiments including a sub-combination of features which may not be explicitly described above. In addition, features from one or more of the above-described example embodiments may be selected and combined to create alternative example embodiments including a combination of features which may not be explicitly described above. Features suitable for such combinations and sub-combinations would be readily apparent to persons skilled in the art upon review of the present application as a whole. The subject matter described herein and in the recited claims intends to cover and embrace all suitable changes in technology

What is claimed is:

1. A computer-implemented method comprising:
receiving a time-series of undersampled scan images obtained using magnetic resonance imaging (MRI);
segmenting the time-series into a plurality of subsets of undersampled scan images and, for each subset, combining the undersampled scan images in the subset to obtain a low-temporal-resolution k-space image for that subset;
generating an estimated spatial domain image for each low-temporal-resolution k-space image to obtain a set of low-temporal-resolution estimated spatial domain images;
generating a subset of representative images based on the set of low-temporal-resolution estimated spatial domain images to form an estimated spatial domain subspace;
for each undersampled scan image in the time-series of undersampled scan images, determining a spatial domain reconstruction as a function of the representative images in the estimated spatial domain subspace; and
outputting, as a sequence of images for video display, the spatial domain reconstructions.

2. The computer-implemented method of claim 1, wherein generating the estimated spatial domain image includes using compressed sensing to generate the estimated spatial domain image.

3. The computer-implemented method of claim 1, wherein generating the estimated spatial domain image includes, for each low-temporal-resolution k-space image, finding a respective estimated spatial domain image that, when transformed to k-space, best matches that low-temporal-resolution k-space image.

4. The computer-implemented method of claim 3, wherein finding the respective estimated spatial domain image includes selecting a candidate image using a minimization expression, wherein the minimization expression includes a distance measure in k-space.

5. The computer-implemented method of claim 4, wherein the minimization expression further includes a temporal total variation term and a nuclear norm.

6. The computer-implemented method of claim 5, wherein the minimization expression is:
$${\hat{x}}_{L} = {min}_{{x}_{L}} \{ {‖ {Hx}_{L} - {y}_{L} ‖}_{2}^{2} + λ {‖ TV ( {x}_{L} ) ‖}_{2}^{2} + γ {‖ {x}_{L} ‖}_{*} \}$$
wherein \hat{x}_{L} is the estimated spatial domain image, x_{L} is the candidate image, y_{L} is the low-temporal-resolution k-space image, H is an undersampling transform, λ and γ are balancing parameters, TV( ) is a numerical gradient in the temporal direction, and ∥⋅∥_{*} is the nuclear norm.

7. The computer-implemented method of claim 1, wherein generating the subset includes performing singular value decomposition to determine a singular value for each representative image, and selecting, as the subset, b of the representative images having the highest associated singular values, wherein b is a present number of basis images.

8. The computer-implemented method of claim 1, wherein determining the spatial domain reconstruction includes determining a set of coefficients that, when applied to the representative images in the subset result in the spatial domain reconstruction.

9. The computer-implemented method of claim 8, wherein, for each undersampled scan image, determining the set of coefficients includes finding a best match in k-space between the undersampled scan image and an undersampled transformed product of the set of coefficients and the estimated spatial domain subspace.

10. The computer-implemented method of claim 1, further comprising re-performing compressed sensing using the spatial domain reconstruction as a candidate image to generate a final spatial domain reconstruction constrained to be close to the spatial domain subspace.

11. The computer-implemented method of claim 1, wherein the time-series of undersampled scan images comprises a time-series of radially sampled k-space scan images, a time-series of Cartesian sampled k-space scan images, or a time-series of spiral sampled k-space scan images.

12. A computing device, comprising:
a processor; and
a memory coupled to the processor and storing processor-executable instructions which, when executed by the processor, are to cause the processor to:
receive a time-series of undersampled scan images obtained using magnetic resonance imaging (MRI);
segment the time-series into a plurality of subsets of undersampled scan images and, for each subset, combine the undersampled scan images in the subset to obtain a low-temporal-resolution k-space image for that subset;
generate an estimated spatial domain image for each low-temporal-resolution k-space image to obtain a set of low-temporal-resolution estimated spatial domain images;
generate a subset of representative images based on the low-temporal-resolution estimated spatial domain images to form an estimated spatial domain subspace;
for each undersampled scan image in the time-series of undersampled scan images, determine a spatial domain reconstruction as a function of the representative images in the estimated spatial domain subspace; and
output, as a sequence of images for video display, the spatial domain reconstructions.

13. The computing device of claim 12, wherein the instructions, when executed by the processor, are to cause the processor to generate the estimated spatial domain image using compressed sensing to generate the estimated spatial domain image.

14. The computing device of claim 12, wherein the instructions, when executed by the processor, are to cause the processor to generate the estimated spatial domain image by, for each low-temporal-resolution k-space image, finding a respective estimated spatial domain image that, when transformed to k-space, best matches that low-temporal-resolution k-space image.

15. The computing device of claim 14, wherein finding the respective estimated spatial domain image includes selecting a candidate image using a minimization expression, wherein the minimization expression includes a distance measure in k-space.

16. The computing device of claim 15, wherein the minimization expression further includes a temporal total variation term and a nuclear norm.

17. The computing device of claim 16, wherein the minimization expression is:
$${\hat{x}}_{L} = {min}_{{x}_{L}} \{ {‖ {Hx}_{L} - {y}_{L} ‖}_{2}^{2} + λ {‖ TV ( {x}_{L} ) ‖}_{2}^{2} + γ {‖ {x}_{L} ‖}_{*} \}$$
wherein \hat{x}_{L} is the estimated spatial domain image, x_{L} is the candidate image, y_{L} is the low-temporal-resolution k-space image, H is an undersampling transform, λ and γ are balancing parameters, TV( ) is a numerical gradient in the temporal direction, and ∥⋅∥_{*} is the nuclear norm.

18. The computing device of claim 12, wherein the instructions, when executed by the processor, are to cause the processor to generate the subset by performing singular value decomposition to determine a singular value for each of the representative images, and selecting, as the subset, b of the representative images having the highest associated singular values, wherein b is a present number of basis images.

19. The computing device of claim 12, wherein the instructions, when executed by the processor, are to cause the processor to determine the spatial domain reconstruction by determining a set of coefficients that, when applied to the representative images in the subset result in the spatial domain reconstruction.

20. The computing device of claim 19, wherein, for each undersampled scan image, determining the set of coefficients includes finding a best match in k-space between the undersampled scan image and an undersampled transformed product of the set of coefficients and the estimated spatial domain subspace.

21. The computing device of claim 12, wherein the instructions, when executed by the processor, are to further cause the processor to re-perform compressed sensing using the spatial domain reconstruction as a candidate image to generate a final spatial domain reconstruction constrained to be close to the spatial domain subspace.

22. The computing device of claim 12, wherein the time-series of undersampled scan images comprises a time-series of radially sampled k-space scan images, a time-series of Cartesian sampled k-space scan images, or a time-series of spiral sampled k-space scan images.
